(19) United States
(12) Patent Application Publication
(10) Pub. No.: US 2006/0125034 A1
(43) Pub. Date: Jun. 15, 2006

(54) Magnetoresistant device and magnetic memory device further comments

(76) Inventors: Kazuhiro Ohba, Miyagi (JP); Masanori Hosomi, Miyagi (JP); Kazuhiro Bessho, Kanagawa (JP); Tetsuya Mizuguchi, Kanagawa (JP); Yutaka Higo, Miyagi (JP); Tetsuya Yamamoto, Kanagawa (JP); Takeyuki Sone, Miyagi (JP); Hiroshi Kang, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 10/523,281

(22) PCT Filed: Aug. 1, 2003
(86) PCT No.: PCT/JP03/09824

§ 371 Date: Oct. 18, 2005

(30) Foreign Application Priority Data
Aug. 7, 2002 (JP) 2002-230367

(51) Int. Cl. H01L 43/00; H01L 29/82

(52) U.S. Cl. 257/421

(57) ABSTRACT

There are provided a magnetoresistive device having excellent magnetic properties and a magnetic memory apparatus including this magnetoresistive device and which has excellent read and write characteristics.

A magnetoresistive device has an arrangement including a pair of ferromagnetic layers (magnetization fixed layer 5 and magnetization free layer 7) being opposed to each other through an intermediate layer 6 to obtain variations in magnetoresistance by an electric current flowing in the direction perpendicular to the film plane. This magnetoresistive device 1 has the pair of ferromagnetic layers 5, 7 composed of the magnetization fixed layer 5 made of a crystalline ferromagnetic layer provided under the intermediate layer 6 and the magnetization free layer 7 being made of an amorphous ferromagnetic layer being provided above the intermediate layer 6, and the magnetic memory apparatus is composed of this magnetoresistive device 1 and a bit line and a word line sandwiching the magnetoresistive device 1 in the thickness direction.

### TECHNICAL FIELD

The present invention relates to a magnetoresistive device having an arrangement to obtain variations in magnetoresistance by an electric current flowing through the direction perpendicular to the film plane and a magnetic memory apparatus including such a magnetoresistive device.

### BACKGROUND ART

As personal small equipment such as information communication equipment, in particular, personal terminal equipment, are making great progress, devices such as memories and logic devices comprising personal small equipment should be requested to become higher in performance such as they should be higher in integration degree, they should be operated at higher speed and they should save much more electric power. In particular, technologies for increasing density and storage capacity of a nonvolatile memory are becoming as more important replacements of a hard disk and an optical disc which cannot be essentially miniaturized because they have movable portions.

As nonvolatile memories, there may be enumerated a flash memory using a semiconductor and an FRAM (Ferro electric Random Access Memory) using a ferroelectric material.

However, the flash memory encounters with a defect in which its write speed is slow in the order of μsecond. On the other hand, in the FRAM, a problem is pointed out in which it cannot be rewritten many times.

As a nonvolatile memory which receives a remarkable attention as a nonvolatile memory which is free from these defects, there is known a magnetic memory called an “MRAM (Magnetic Random Access Memory)” which has been described in “Wang et al., IEEE Trans. Magn. 33 (1997), 4498”. This MRAM is simple in structure and hence it can be increased in integration degree with ease. Also, this magnetic random access memory can write information based upon rotation of magnetic moment and hence it can be rewritten so many times. Further, it is expected that an access time of this magnetic random access memory will be very high and it was already confirmed that the magnetic random access memory can be operated in the order of nanosecond.

A magnetoresistive device for use in this MRAM, in particular, a tunnel magnetoresistive (Tunnel Magnetoresistance: TMR) device is fundamentally comprised of a laminated structure of ferromagnetic layer/tunnel barrier layer/ferromagnetic layer. A magnetoresistive effect appears in this device in response to a relative angle of magnetizations of two magnetic layers when an external magnetic field is applied between the ferromagnetic layers under the state in which a constant electric current is flowing through the ferromagnetic layers. When the magnetization directions of the two ferromagnetic layers are anti-parallel to each other, a resistance value is maximized. When the magnetization directions of the two ferromagnetic layers are parallel to each other, a resistance value is minimized. Function of the memory device can be realized when the anti-parallel state and parallel state of the magnetizations are generated with application of the external magnetic field.

In particular, in a spin-valve type TMR device, when one ferromagnetic layer is coupled to the adjacent antiferromagnetic layer in an antiferromagnetic fashion, it may serve as a magnetization fixed layer of which magnetization direction is always made constant. The other ferromagnetic layer may serve as a magnetization free layer of which magnetization direction is easily inverted with application of the external magnetic field. Then, this magnetization free layer may serve as an information recording layer in the magnetic memory.

In the spin-valve type TMR device, a variation of its resistance value is expressed by the following equation (A):
2P1P2/(1−P1P2) (A)
where P1 and P2 represent spin polarizabilities of the respective ferromagnetic layers.

As described above, the variations of resistance increase as the respective spin polarizabilities increase.

The fundamental arrangement of the MRAM comprises, as is disclosed in official gazette of Japanese laid-open patent application No. 10-116490, a plurality of bit write lines (so-called bit lines), a plurality of word write lines (so-called word lines) perpendicular to these bit write lines and TMR devices disposed at intersection points between these bit write lines and word write lines as magnetic memory devices. Then, when information is written in the MRAM, information is selectively written in the TMR device by using an asteroid characteristic.

The bit write line and the word write line for use with the MRAM are made of conductive thin films such as Cu or Al that has been usually used in semiconductors, and an electric current of about 2 mA has been required to write information in a device of which inverted magnetic field is 20 Oe by a write line with a line width of a 0.25 μm. When the thickness of the write line is the same as that line width, an electric current density obtained at that time reaches 3.2×10⁶ A/cm, which is close to a limit value at which a wire is broken by electro-migration. Also, there arises a problem of heat generated by a write electric current, and from a standpoint of decreasing power consumption, it is necessary to decrease this write electric current.

As a method for realizing decrease of a write electric current in the MRAM, there may be enumerated a method of decreasing a coercivity of the TMR device. The coercivity of the TMR device may be properly determined by suitable factor such as size, shape, film arrangement of a device and selection of material of the device.

However, when the TMR device is microminiaturized in order to increase a recording density of the MRAM, for example, there occurs a disadvantage that the coercivity of the TMR device will increase.

Accordingly, in order to achieve microminiaturization (increase of integration degree) of the MRAM and to decrease the write electric current at the same time, it is necessary to achieve decrease of the coercivity of the TMR device from a material standpoint.

Also, if magnetic properties of the TMR device are changed at every device in the MRAM or magnetic properties are changed when the same device is used repeatedly, there arises a problem in which it becomes difficult to selectively write information in the device by using the asteroid characteristic.

Accordingly, the TMR device is requested to have magnetic properties by which an ideal asteroid curve can be drawn.

In order to draw an ideal asteroid curve, the tunnel magnetoresistive device should be free from noises such as a Barkhausen noise in an R-H (resistance-magnetic field) loop obtained when the TMR ratio is measured, it should have excellent waveform rectangle properties, stable magnetized state and small dispersions of a coercivity Hc.

Information is read out from the TMR device of the MRAM by a difference electric current at a constant bias voltage or a difference voltage at a constant bias current obtained in the state of “1” presented when the directions of the magnetic moments of one ferromagnetic layer and the other ferromagnetic layer sandwiching a tunnel barrier layer are in the anti-parallel state and wherein a resistance value is high and in the state of “0” presented when the directions of the magnetic moments of the two ferromagnetic layers are in the parallel state.

Accordingly, when dispersions of resistances between the devices are the same, a higher TMR ratio (variation in magnetoresistance) is advantageous so that a high-speed device with a high integration degree and which is low in error rate can be realized.

Further, it is known that a bias voltage dependence of a TMR ratio exists in a TMR device having a fundamental structure of ferromagnetic layer/tunnel barrier layer/ferromagnetic layer so that the TMR ratio decreases as the bias voltage increases. Since it is known that, when information is read out from the device by the difference electric current or the difference voltage, in most cases, the TMR ratio takes a maximum value of a read signal at a voltage (Vh) which is decreased half by the bias voltage dependence, a smaller bias voltage dependence is effective for decreasing a read error.

Accordingly, the TMR device for use with the MRAM should satisfy the above-mentioned write characteristic requirements and read characteristic requirements at the same time.

However, when the material of the ferromagnetic layer of the TMR device is selected, if the alloy composition for increasing the spin polarizabilities shown by P1 and P2 in the equation (A) is selected from Co, Fe, Ni ferromagnetic transition metal elements, then it is customary that the coercivity Hc of the TMR device tends to increase.

When CO₇₅Fe₂₅ (atomic %) alloy or the like, for example, is used to form a magnetization free layer (free layer), that is, information recording layer, although the spin polarizability is large and a high TMR ratio higher than 40% can be maintained, the coercivity Hc also increases.

On the other hand, when an Ni₈₀Fe₂₀ (atomic %) alloy called permalloy that is known as a soft magnetic material is in use, although the coercivity Hc can be decreased, the spin polarizability is low as compared with that of the above-mentioned CO₇₅Fe₂₅ (atomic %) alloy so that a TMR ratio is lowered to about 33%.

Further, when a Co₉₀Fe₁₀ (atomic %) alloy having an intermediate characteristic between those of the alloys of the above-mentioned two compositions, although a TMR ratio of about 37% can be obtained and the coercivity Hc can be suppressed to approximately a middle coercivity between the coercivity of the above-mentioned CO₇₅Fe₂₅ (atomic %) alloy and the coercivity of the above-mentioned Ni₈₀Fe₂₀ (atomic %) alloy, rectangle ratios of the R-H loop are poor and the asteroid characteristic for enabling information to be written in the device cannot be obtained.

In order to solve the above-mentioned problems, the present invention is to provide a magnetoresistive device having excellent magnetic properties and a magnetic memory apparatus read and write characteristics.

### DISCLOSURE OF THE INVENTION

A magnetoresistive device according to the present invent has an arrangement in which a pair of ferromagnetic layers is opposed to each other to obtain variations in magnetoresistance by an electric current flowing to the direction perpendicular to the film plane. This magnetoresistive device is characterized in that the pair of ferromagnetic layers is composed of a magnetization fixed layer made of a crystalline ferromagnetic layer provided under the intermediate layer and a magnetization free layer being made of an amorphous ferromagnetic layer being provided above the intermediate layer.

A magnetic memory apparatus according to the present invention comprises a magnetoresistive device having a pair of ferromagnetic layers opposed to each other to obtain variations in magnetoresistance by an electric current flowing to the direction perpendicular to the film plane and a word line a bit line sandwiching the magnetoresistive device in the thickness direction, wherein the magnetic memory apparatus includes the pair of ferromagnetic layers composed of a magnetization fixed layer made of a crystalline ferromagnetic layer provided under the intermediate layer and a magnetization free layer being made of an amorphous ferromagnetic layer being provided above the intermediate layer.

According to the above-mentioned arrangement of the magnetoresistive device of the present invention, since the pair of ferromagnetic layers is composed of the magnetization fixed layer made of the crystalline ferromagnetic layer provided under the intermediate layer and the magnetization free layer made of the amorphous ferromagnetic layer provided above the intermediate layer, the coercivity can be decreased by the magnetization free layer made of the amorphous ferromagnetic layer, the rectangle properties of the resistance-magnetic field curve can be improved, the bias voltage dependence of the variations in magnetoresistance can be improved and the dispersions of the coercivity can be decreased.

Further, since the magnetization fixed layer made of the crystalline ferromagnetic layer is provided under the intermediate layer, it becomes possible to realize the high variations in magnetoresistance.

According to the above-mentioned arrangement of the magnetic memory apparatus of the present invention, since the magnetic memory apparatus includes the magnetoresistive device and the word line and the bit line sandwiching the magnetoresistive device in the thickness direction wherein the magnetoresistive device has the arrangement of the above-described magnetoresistive device of the present invention, the rectangle properties of the resistance-magnetic field curve of the magnetoresistive device can be increased, the bias voltage and the dispersion of the coercivity can be decreased. As a result, the asteroid characteristic of the magnetoresistive device can be improved and it becomes possible to selectively write information in the magnetic memory apparatus with ease stably. That is, the write characteristic can be increased and hence the write error can be decreased.

Also, since it becomes possible to increase the variation in magnetoresistance of the magnetoresistive device, when information is read out from the magnetic memory apparatus, it becomes easy to discriminate the low resistance state and the high resistance state from each other. As a consequence, the read characteristic can be improved and hence the read error can be decreased.

### BRIEF DESCRIPTION OF DRAWINGS

FIG. 1 is a schematic diagram of an arrangement of a TMR device according to an embodiment of the present invention;

FIG. 2 are diagrams showing measured results obtained when resistance-external magnetic field curves of a TMR device are compared with each other, wherein FIG. 2A is a diagram showing measured results obtained when resistance-external magnetic field curve of a tunnel magnetoresistive device comprising a magnetization free layer made of an amorphous ferromagnetic layer and a magnetization free layer made of a crystalline ferromagnetic material are compared with each other, FIG. 2B is external magnetic field curves of a tunnel magnetoresistive device comprising a magnetization free layer and a magnetization free layer both of made of crystalline ferromagnetic materials are compared with each other, and FIG. 2C is a diagram showing measured results obtained when resistance-external magnetic curves of a tunnel magnetoresistive device comprising a magnetization free layer and a magnetization fixed layer both made of amorphous ferromagnetic materials are compared with each other;

FIG. 3 is a schematic diagram showing an arrangement of a TMR device including a laminated ferri structure;

FIG. 4 a schematic diagram showing an arrangement of a main portion of a cross-point type MRAM array using TMR devices according to the present invention as memory cells;

FIG. 5 is a cross-sectional view showing the memory cell shown in FIG. 4 in an enlarged-scale;

FIG. 6 is a plan view of a TEG for evaluating a TMR device; and

FIG. 7 is a cross-sectional view taken along the line A-A in FIG. 6.

### BEST MODE FOR CARRYING OUT THE INVENTION

According to the present invention, in a magnetoresistive device comprising a pair of ferromagnetic layers opposed to each other through an intermediate layer to obtain variations in magnetoresistance with application of an electric current flowing through the direction perpendicular to the film plane, a magnetoresistive device comprises, of the pair of ferromagnetic layers, a magnetization fixed layer composed of a crystalline ferromagnetic layer formed under the intermediate layer and a magnetization free layer composed of an amorphous ferromagnetic layer formed above the intermediate layer.

Also, according to the present invention, in the above-described magnetoresistive device, the magnetoresistive device has a laminated ferri structure.

Also, according to the present invention, in the above-described magnetoresistive device, the magnetoresistive device is a tunnel magnetoresistive device using a tunnel barrier layer made of an insulating material or a semiconductor material as the intermediate layer.

According to the present invention, there is provided a magnetic memory apparatus including a magnetoresistive device comprising a pair of ferromagnetic layers opposed to each other through an intermediate layer to obtain variations in magnetoresistance with application of an electric current flowing through the direction perpendicular to the film plane and a word line and a bit line sandwiching this magnetoresistive device in the thickness direction, wherein, of the pair of ferromagnetic layers, a magnetization fixed layer made of a crystalline ferromagnetic layer is formed under the intermediate layer, a magnetization free layer made of an amorphous ferromagnetic layer is formed above the intermediate layer.

Also, according to the present invention, in the above-described magnetic memory apparatus, the magnetoresistive device has a laminated ferri structure.

Further, according to the present invention, in the above-described magnetic memory apparatus, the magnetoresistive device is a tunnel magnetoresistive device using a tunnel barrier layer made of an insulating material or a semiconductor material as the intermediate layer.

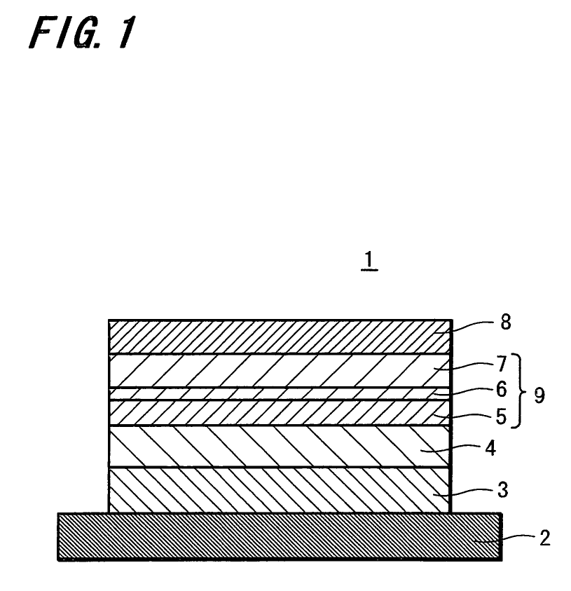

First, FIG. 1 is a schematic diagram showing an arrangement of a magnetoresistive device according to an embodiment of the present invention. This embodiment shown in FIG. 1 shows the case in which the present invention is applied to a tunnel magnetoresistive device (hereinafter referred to as a TMR device).

This TRM device 1 includes a substrate 2 made of a suitable material such as silicon on which there are laminated an underlayer 3, an antiferromagnetic layer 4, a magnetization fixed layer 5 serving as a ferromagnetic layer, a tunnel barrier layer 6, a magnetization free layer 7 serving as a ferromagnetic layer and a top-coat layer 8, in that order.

More specifically, this tunnel magnetoresistive device is a so-called spin-valve type TMR device in which one of the ferromagnetic layer is formed as the magnetization fixed layer 5, the other one being formed as the magnetization free layer 7. The magnetization fixed layer 5 and the magnetization free layer 7, which are the pair of ferromagnetic layers, sandwich the tunnel barrier layer 6 to form a ferromagnetic tunnel junction 9.

Then, when this TMR device 1 is applied to a suitable apparatus such as a magnetic memory apparatus, the magnetization free layer 7 is used as an information recording layer in which information is recorded.

The antiferromagnetic layer 4 is a layer to prevent the magnetization of the magnetization fixed layer 5 from being inverted with application of an electric current magnetic field for writing so that the magnetization direction of the magnetization fixed layer 5 can always be made constant when it is coupled to the magnetization fixed layer 5 serving as one of the ferromagnetic layers in an antiferromagnetic fashion. That is, in the TMR device 1 shown in FIG. 1, the magnetization direction of only the magnetization free layer 7 serving as the other ferromagnetic layer with application of an external magnetic field or the like. The magnetization free layer 7 becomes the layer to record information thereon when the TMR device 1 is applied to a suitable apparatus such as a magnetic memory device and therefore it is also referred to as an information recording layer.

Mn alloys containing Fe, Ni, Pt, Ir, Rh or the like, Co oxide, Ni oxide and the like can be used as the material comprising the antiferromagnetic layer 4.

Although not limited in particular, alloy materials composed of one kind or more than two kinds of iron, nickel, cobalt can be used as the ferromagnetic material comprising the magnetization fixed layer 5.

In the spin-valve type TMR device 1 shown in FIG. 1, the magnetization fixed layer 5 is coupled to the antiferromagnetic layer 4 in an antiferromagnetic fashion and thereby the magnetization direction thereof is made constant. For this reason, the magnetization direction of the magnetization fixed layer 5 may not be inverted with application of an electric current magnetic field which is used to write information.

The tunnel barrier layer 6 is adapted to magnetically separate the magnetization fixed layer 5 and the magnetization free layer 7 and is also used to cause a tunnel electric current to flow therethrough.

Oxide such as Al, Mg, Si, Il, Ca, nitride, insulating materials such as halide can be used as the material comprising the tunnel barrier layer 6.

This tunnel barrier layer 6 can be obtained by oxidizing or nitriding a metal film which was deposited by a suitable method such as a sputtering method or a vapor deposition method.

Also, the above-mentioned tunnel barrier layer can be obtained by a CVD method using organic metals and oxygen, ozone, nitrogen, halogen, halogenated gas and the like.

In this embodiment, the magnetization free layer 7 (adjoining the upper surface of the tunnel barrier layer) on the tunnel barrier layer 6, in particular, is made of an amorphous ferromagnetic material and the magnetization fixed layer 5 (adjoining the lower surface of the tunnel barrier layer) of the tunnel barrier layer 6 is made of a crystalline ferromagnetic material.

The conventional TMR device in which the ferromagnetic layers are made of ferromagnetic transition metal elements (Fe, Co, Ni, etc.) encounters with the disadvantage in which coercivity is unavoidably increased as the spin polarizability is increased as mentioned hereinbefore.

Accordingly, since the magnetization direction of the magnetic material of the magnetization free layer can be inverted stably by using the amorphous ferromagnetic material as the magnetization free layer 7, rectangle properties of R-H curves can be improved and stability of shape of an asteroid curve of the TMR device and which relates to reading of information when the tunnel magnetoresistive device is applied to the magnetic memory apparatus such as the MRAM can be improved.

Further, the magnetization free layer 7 made of the amorphous ferromagnetic material is disposed on the tunnel barrier layer 6 and the magnetization fixed layer 5 made of the crystalline ferromagnetic material is disposed on the tunnel variation) can be increased.

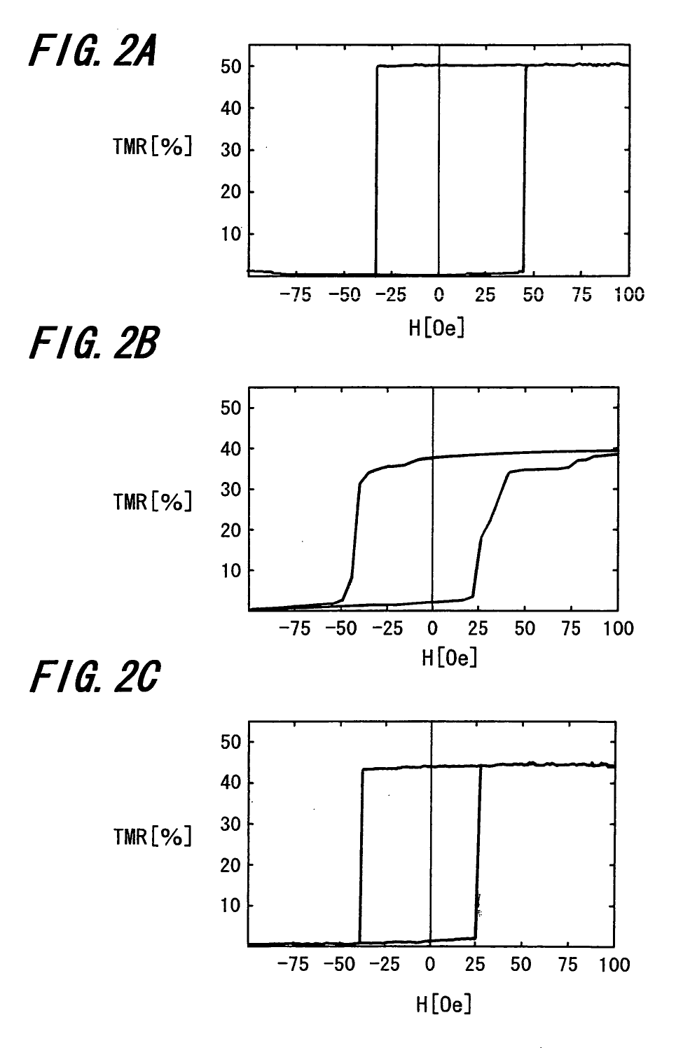

FIG. 2A shows measured results of resistance-external magnetic curves of a spin-valve type TMR device having an arrangement in which the magnetization fixed layer 5 disposed under the tunnel barrier layer 6 is made of a crystalline silicon ferromagnetic material having a composition of CO₇₅Fe₂₅ (atomic %), the magnetization free layer 7 disposed above the tunnel barrier layer 6 being made of an amorphous ferromagnetic material having a composition of (CO₉₀Fe₁₀)₈₀B₂₀ (atomic %).

Also, FIG. 2B shows measured results of resistance-external magnetic field curves of a spin-valve type TMR device having an arrangement in which the magnetization fixed layer disposed under the tunnel barrier layer and the magnetization free layer disposed above the tunnel barrier layer are both made of a crystalline ferromagnetic material having a composition of CO₇₅Fe₂₅ (atomic %).

Further, FIG. 2C shows measured results of resistance-external magnetic field curves of a spin-valve type TMR device having an arrangement in which the magnetization fixed layer disposed under the tunnel barrier layer and the magnetization free layer disposed above the tunnel barrier layer are both made of an amorphous ferromagnetic material having a composition of (Co₉₀Fe₁₀)₈₀B₂₀ (atomic %).

In each of the diagrams of FIGS. 2A, 2B and 2C, the vertical axis represents a TMR (ratio in which a resistance is changed by a tunnel magnetoresistive effect) in the form of % instead of specific measured values of resistance.

As will be clear from compared results of FIGS. 2A and 2B, the TMR device 1 having the arrangement in which the magnetization fixed layer 5 is made of the crystalline ferromagnetic material, the magnetization free layer 7 being made of the amorphous ferromagnetic material could increase a TMR ratio (variation in tunnel magnetoresistance) corresponding to the maximum value of TMR in each of the diagrams and can decrease the coercivity Hc as compared with the TMR device having an arrangement in which the magnetization fixed layer and the magnetization free layer are both made of the crystalline ferromagnetic materials. In FIG. 2A, a TMR ratio is approximately 50% and the coercivity Hc is close to 35 Oe, and in FIG. 2B, a TMR ratio is approximately 32% and the coercivity Hc is close to 40 Oe. Also, it is to be understood that the tunnel magnetoresistive device shown in FIG. 2A could improve rectangle properties of R-H curves more and that it could decrease a Barkhausen noise more.

Accordingly, it is to be understood that the TMR device 1 in which the magnetization fixed layer 5 is made of the crystalline ferromagnetic material, the magnetization free layer 7 being made of the amorphous ferromagnetic material becomes able to decrease a tunnel electric current and that it can improve the shape of the asteroid curve. Thus, when the tunnel magnetoresistive device according to the present invention is applied to the magnetic memory apparatus such as the MRAM, it becomes possible to decrease write errors by improving a write characteristic.

On the other hand, it is to be understood from FIG. 2C that a TMR ratio can be decreased to about 38% when the magnetization fixed layer disposed under the tunnel barrier layer and the magnetization free layer disposed above the tunnel barrier layer are both made of the amorphous ferromagnetic material.

Accordingly, in order to stabilize the magnetization direction inverting behavior of the magnetization free layer and also in order to obtain a high TMR ratio, it is desirable that the magnetization fixed layer 5 disposed under the tunnel barrier layer 6 should be made of the crystalline ferromagnetic material and that the magnetization free layer 7 disposed above the tunnel barrier layer 6 should be made of the amorphous ferromagnetic material like the embodiment of the present invention.

The cause for this is not always clear at present but it is considered that, when the ferromagnetic layer (the upper surface thereof adjoins the tunnel barrier layer) disposed under the tunnel barrier layer is made of the amorphous ferromagnetic material, through an annealing process adopted by the process for producing a TMR device, the amorphous ferromagnetic layer is crystallized, smoothness of a boundary surface of amorphous ferromagnetic layer/tunnel barrier layer is inhibited or amorphous elements are diffused into the antiferromagnetic layer and the nonmagnetic layer of the laminated ferri structure to exert a bad influence on a magnetoresistive effect.

Since a tunnel barrier layer made of Al—Oₓ, for example, has an amorphous structure, it is relatively easy to form the amorphous ferromagnetic material on the upper surface of the tunnel barrier layer.

On the other hand, if the amorphous ferromagnetic layer is formed on the crystalline antiferromagnetic layer as the magnetization fixed layer, then it is difficult to form the amorphous structure in actual practice due to an influence of crystal orientation of the antiferromagnetic layer. As a consequence, it is frequently observed that the amorphous structure will be crystallized due to annealing or the like.

For this reason, in such case, it is considered that properties of a TMR device such as a variation in magnetoresistance are lowered as compared with the case in which the crystalline ferromagnetic layer is used as the magnetization fixed layer.

Accordingly, it is desired that the ferromagnetic layer formed on the tunnel barrier layer should be made of a crystalline ferromagnetic material free from a defect in which a crystal structure is changed such as to be crystallized by annealing or the like and which is also free from a risk that an amorphous element will be diffused into other (undesirable) layer.

As the amorphous ferromagnetic material for use with the magnetization free layer 7, there can be used amorphous alloys in which metalloid elements such as B, Si, C, O which are called metalloid elements, valve metals such as Ti, Zr, Ta, Nb and further rare earth elements such as Y, La, Ve, Nd, Dy, Gd are added to Fe-group ferromagnetic elements such as Fe, Co, Ni.

According to the above-mentioned TMR device 1 of this embodiment, since the TMR device 1 has the arrangement in which the magnetization free layer 7 (adjoining the upper surface of the tunnel barrier layer) disposed on the tunnel barrier layer 6 is made of the amorphous ferromagnetic material and the magnetization fixed layer 5 (adjoining the lower surface of the tunnel barrier layer) disposed under the tunnel barrier layer is made of the crystalline ferromagnetic material, the magnetization direction of the ferromagnetic material of the magnetization free layer 7 can be inverted stably.

As a result, the rectangle properties of the resistance-magnetic field curve (R-H curve) can be improved, the Barkhausen noise can be decreased and the coercivity Hc can be decreased. Since the Barkhausen noise can be decreased, it becomes possible to decrease dispersions of the coercivity Hc.

Then, a bias voltage dependence of a TMR ratio (variation in tunnel magnetoresistance) can be improved and hence the TMR ratio can be increased as compared with the case in which the magnetization free layer is made of the crystalline ferromagnetic material.

Since the dispersions of the coercivity Hc can be suppressed and the shape of the asteroid curve of the TMR device 1 can be improved as described above, when the TMR device 1 is applied to a magnetic memory apparatus including a large number of TMR devices, information can selectively be written with ease.

Also, when the present invention is applied to a magnetic head or a magnetic sensor including TMR devices, it becomes possible to improve a yield in the manufacturing process and to prevent mis-operations by suppressing displacement of the inverted magnetic field from a designed value.

Further, since the magnetization fixed layer 5 made of the crystalline ferromagnetic material is disposed under the tunnel barrier layer 6, there can be obtained a high TMR ratio (variation in tunnel magnetoresistance) as compared with the case in which the magnetization fixed layer is made of the amorphous ferromagnetic material.

More specifically, it is possible to realize, especially, a high TMR ratio (variation in tunnel magnetoresistance) by combining the magnetization fixed layer 5 made of the crystalline ferromagnetic material under the tunnel barrier layer 6 and the magnetization free layer 7 made of the amorphous ferromagnetic material above the tunnel barrier layer 6.

Since the TMR ratio of the TMR device 1 can be increased as described above, when the TMR device 1 is applied to a magnetic memory apparatus including a large number of TMR devices, the low resistance state and the high resistance state can be discriminated with ease and thereby information can be read out from the magnetic memory apparatus.

Also, when the present invention is applied to a magnetic head or a magnetic sensor including TMR devices, since the TMR ratio can be increased and a magnetic field from a magnetic recording medium or an output from the TMR device 1 relative to an external magnetic field can be increased, it becomes possible to increase reproducing sensitivity of the magnetic recording medium or to increase sensitivity of the magnetic sensor.

The present invention is not limited to the TMR device 1 in which each of the magnetization fixed layer 5 and the magnetization free layer 7 is composed of a single layer as shown in FIG. 1.

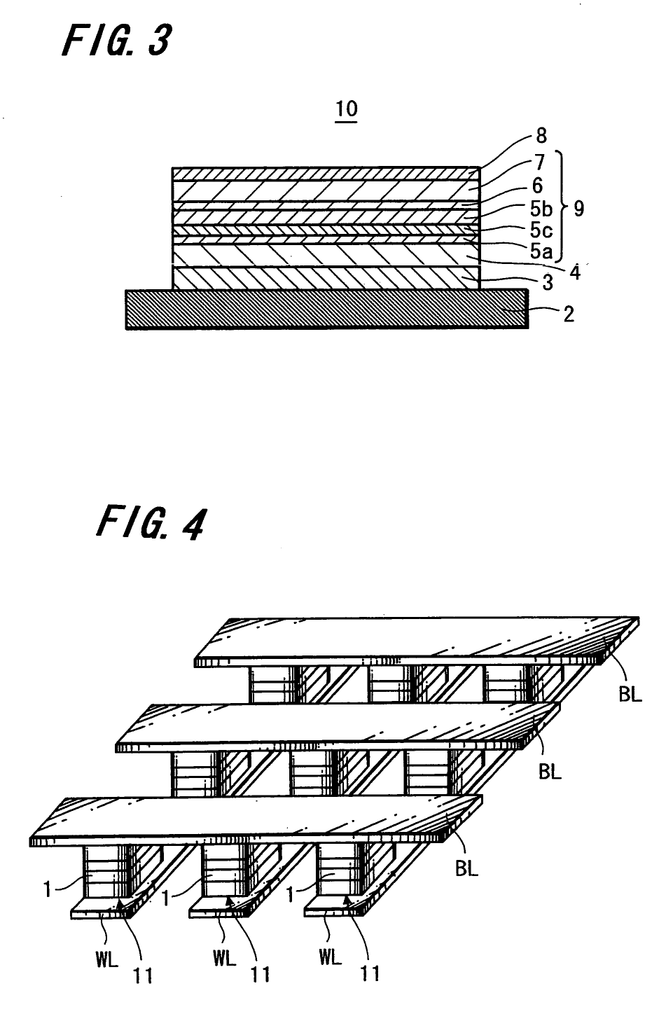

Even when the tunnel magnetoresistive device has the laminated ferri structure in which the magnetization fixed layer 5 includes a nonmagnetic conductive layer 5c sandwiched by a first magnetization fixed layer 5a and a second magnetization fixed layer 5b as shown in FIG. 3, for example.

In a TMR device 10 shown in FIG. 3, since the first magnetization fixed layer 5a adjoins the antiferromagnetic layer 4, the first magnetization fixed layer 5a is given strong magnetic anisotropy of one direction by exchange interaction acting between these first magnetization fixed layer and antiferromagnetic layer. Also, since the second magnetization fixed layer 5b is opposed to the magnetization free layer 7 through a tunnel barrier layer 6, the spin direction of the second magnetization fixed layer is compared with that of the magnetization free layer 7, the second magnetization fixed layer acts as a ferromagnetic layer which is directly concerned with an MR ratio and hence it is referred to as a reference layer.

Ru, Rh, Ir, Cu, Cr, Au, Ag and the like may be used as a material for use in the nonmagnetic conductive layer 5c having the laminated ferri structure. In the TMR device 10 shown in FIG. 3, other layers have substantially similar arrangements to those of the TMR device 1 shown in FIG. 1. Hence, other layers are denoted by reference numerals identical to those of FIG. 1 and therefore need not be described in detail.

Also in the TMR device 10 having this laminated ferri structure, a magnetization fixed layer, in particular, a second magnetization fixed layer 5b, which is a magnetization fixed layer of a tunnel barrier layer 6, is made of a crystalline ferromagnetic layer and a magnetization free layer 7 on the tunnel barrier layer 6 is made of an amorphous ferromagnetic material, whereby rectangle properties of a resistance-magnetic field curve (R-H curve) can be improved, a Barkhausen noise can be decreased and a coercivity Hc can be decreased similarly to the TMR device 1 shown in FIG. 1. Also, since it becomes possible to decrease dispersions of the coercivity Hc. Further, it is possible to realize a high TMR ratio (variation in tunnel magnetoresistance).

While the TMR devices (tunnel magnetoresistive devices) 1, 11 are used as the magnetoresistive device in the above-mentioned embodiment, the present invention can also be applied to other magnetoresistive device having an arrangement including a pair of ferromagnetic layers opposed to each other through an intermediate layer to obtain variations in magnetoresistance by an electric current flowing through the direction perpendicular to the film plane.

For example, the present invention can also be applied to a giant magnetoresistive device (GMR device) using a nonmagnetic conductive layer such as Cu as an intermediate layer and which has an arrangement to obtain a magnetoresistance effect by an electric current flowing through the direction perpendicular to the film plane, that is, so-called CPP type GMR device.

(Dispersions of Coercivity Hc)

R-H curves were obtained by the above-described TMR ratio measuring methods. Then, mean values of the resistance values obtained in the state in which the magnetization directions of the magnetization fixed layer and the magnetization free layer are in the anti-parallel state and in which the resistance is high and the resistance values obtained in the state in which the magnetization directions of the magnetization fixed layer and the magnetization free layer are in the parallel state and in which the resistance is low are calculated from the R-H curves, and the value of the external magnetic field under which the resistance value of this average value can be obtained was set to the coercivity Hc. A standard deviation Δ Hc was obtained by measuring this coercivity Hc of the same device (TEG) 50 times. Then, ΔHc/(mean value of Hc) was set to dispersion of the value of the coercivity Hc.

From a standpoint of improving write characteristics, the coercivity Hc should preferably be selected to be less than 6%, more preferably selected to be less than 4%.

(Measurement of Rectangle Ratio)

Rectangle ratios of waveforms were calculated from the R-H curves. That is, a ratio (R2max−R2 min)/(R1max−Rmin) between R1max−R1min in the R-H curve obtained in the magnetic field range from −500 Oe to +500 Oe upon measurement and R2max−R2 min was calculated and this value was set to the rectangle ratio.

From a standpoint of improving the write characteristic, the rectangle ratio should preferably be selected to be greater than 0.9 (90%).

The table 1 shows the TMR ratios and the dispersions of the coercivity Hc with respect to respective samples 1 to 19.

TABLE 1

| | TMR | Dispersions | |
|---|---|---|---|
| Sample | ratio | of Hc | Rectangle |
| No. | (%) | (1σ %) | ratio (%) |
| 1 | 37% | 11% | 76% |
| 2 | 50% | 3.40% | 98% |
| 3 | 44% | 4.00% | 98% |
| 4 | 35% | 1.30% | 74% |
| 5 | 43% | 7.00% | 81% |
| 6 | 54% | 3.10% | 99% |
| 7 | 43% | 4.20% | 98% |
| 8 | 43% | 5.10% | 98% |
| 9 | 48% | 3.60% | 98% |
| 10 | 49% | 3.50% | 98% |
| 11 | 46% | 3.40% | 97% |
| 12 | 55% | 2.80% | 99% |
| 13 | 49% | 2.60% | 99% |
| 14 | 48% | 2.70% | 99% |
| 15 | 50% | 3.00% | 99% |
| 16 | 51% | 2.80% | 99% |
| 17 | 47% | 2.60% | 99% |
| 18 | 43% | 2.60% | 99% |
| 19 | 44% | 4.30% | 96% |

The results on the table 1 will be considered below. Any of the samples has the layer arrangement of the antiferromagnetic layer/first magnetization fixed layer (pinned layer)/nonmagnetic layer/second magnetization fixed layer (reference layer)/insulating layer (tunnel barrier layer)/magnetization free layer.

First, the samples 1 to 4 are compared with each other.

Having compared the sample 2 in which the ferromagnetic layer (adjoining the lower surface of the insulating layer) disposed under the magnetoresistive device having the arrangement to obtain variations in magnetoresistance by an electric current flowing through the direction perpendicular to the film plane.

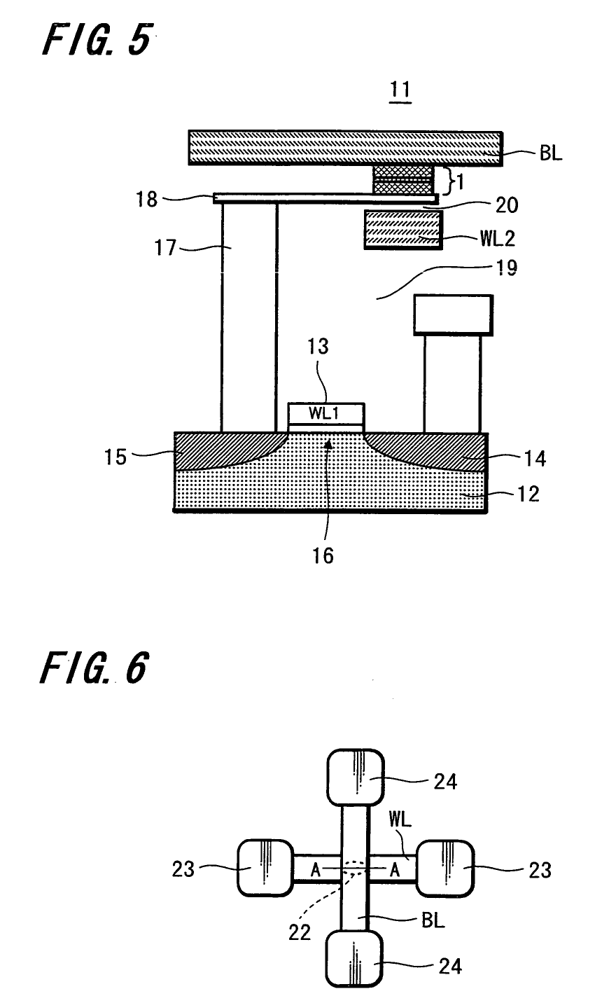

FIG. 5 shows a cross-sectional structure of one memory cell picked up from a large number of memory cells in the memory device.

Each memory cell 11 includes a silicon substrate 12, for example, on which a transistor 16, composed of a gate electrode 13, a source region 14 and a drain region 15, is disposed as shown in FIG. 5. The gate electrode 13 constructs a read word line WL1. A write word line (equivalent to the aforementioned word write line) WL2 is formed on the gate electrode 13 through an insulating layer. A contact metal 17 is connected to the drain region 15 of the transistor 16 and further an underlayer 18 is connected to the contact metal 17. This underlayer 18 has the TMR device 1 of the present invention formed at its position corresponding to the upper portion of the write word line WL2. The bit line (equivalent to the aforementioned bit write line) BL perpendicular to the word lines WL1 and WL2 is formed on this TMR device 1. The underlayer 18 plays the role of electrically connecting the TMR device 1 and the drain region 15 which are located at the different positions on the plane and therefore it is called a bypass.

Also, each memory cell further includes an interlayer insulator 19 and an insulating film 20 for insulating the respective word lines WL1, WL2 and the TMR device 1 and a passivation film (not shown) for protecting the whole of the memory cell.

Since this MRAM uses the TMR device 1 having the arrangement in which the magnetization free layer 7 (adjoining the upper surface of the tunnel barrier layer) on the tunnel barrier layer is made of the amorphous ferromagnetic material, the magnetization fixed layer 5 (adjoining the lower surface of the tunnel barrier layer) under the tunnel barrier layer 6 being made of the crystalline ferromagnetic layer, the bias voltage dependence of the TMR ratio of the TMR device 1 can be improved and the high TMR ratio can be realized. As a result, the low resistance state and the high resistance state can be discriminated with ease, and it is possible to decrease read errors by improving a read characteristic.

Also, since noises are decreased in the resistance-magnetic field curve (R-H curve), the coercivity can become uniform and hence the asteroid characteristic can be improved, information can selectively be written with ease, a write characteristic can be improved and write errors can be decreased.

Accordingly, it is possible to realize the MRAM that can satisfy the read characteristic and the write characteristic at the same time.

### INVENTIVE EXAMPLES

Specific inventive examples to which the present invention is applied will be described with reference to the experiment results.

While the MRAM includes the switching transistor 16 except the TMR device 1 as shown in FIG. 1, according to the inventive examples, in order to examine TMR properties, properties were measured and evaluated by a wafer in which only a ferromagnetic

<Sample 1>

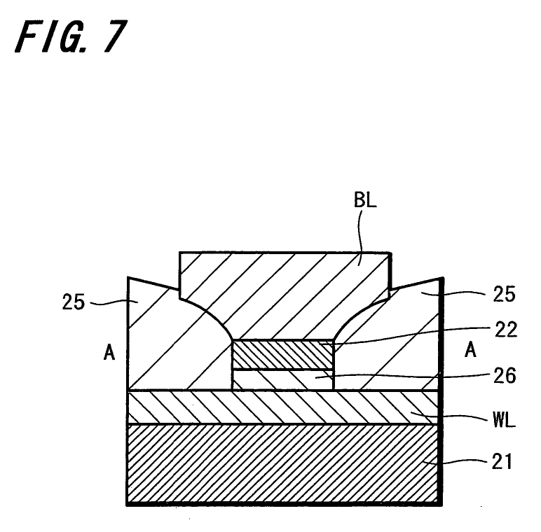

As FIG. 6 shows a plan view and FIG. 7 shows a cross-sectional view taken along the line A-A in FIG. 6, as a characteristic evaluation device TEG (Test Element Group), there was manufactured a test element group having a structure in which the word line W1 and the bit line BL are disposed on the substrate 21 in such a manner as to become perpendicular to each other, a TMR device 22 being formed at the portion in which these word line WL and bit line BL cross each other. This TEG has an arrangement in which the TMR device 22 is shaped like an ellipse having a minor axis of 0.5 μm×a major axis of 1.0 μm, terminal pads 23, 24 are respectively formed at both ends of the word line WL and the bit line BL, the word line WL and the bit line BL being electrically isolated from each other by insulating films 25, 26, each of which is made of Al₂O₃.

To be concrete, the TEG shown in FIGS. 6 and 7 was manufactured as follows.

First, there was prepared a 0.6 mm-thick silicon substrate 21 in which a heat oxide film (thickness is 2 μm) was formed on the surface.

Next, a material of a word line was deposited on this substrate 21 and masked by photolithography, whereafter other portion than the word line was selectively etched away by Ar plasma and thereby the word line WL was formed. At this time, other areas than the word line WL were etched up to the depth 5 nm of the substrate 21.

After that, the insulating layer 26 was formed over the word line WL and the surface was planarized.

Subsequently, a TMR device 22 having the following layer arrangement was manufactured by a well-known lithography method and etching. In this layer arrangement, the left-hand side of the slash represents the substrate side and numerical values within parentheses represent film thicknesses.

Ta (3 nm)/PtMn (20 nm)/Co₉₀Fe₁₀ (2.5 nm)/Ru (0.8 nm)/Co₉₀Fe₁₀ (3 nm)/Al (1 nm)-Oₓ/Co₉₀Fe₁₀ (3 nm)/Ta (5 nm)

It was confirmed by observation through a TEM (transmission electron microscope) that Co₉₀Fe₁₀ has a crystalline structure.

The Al—Oₓ film of the tunnel barrier layer 6 was formed in such a manner that a metal Al film is plasma-oxidized by plasma from ICP (induced coupling plasma) with a oxygen/argon flow rate of 1:1 under chamber gas pressure of 0.1 mTorr after the metal Al film having a film thickness of 1 nm was deposited by a DC sputtering method. Although the oxidation time depends upon the ICP plasma output, it was selected to be 30 seconds in this inventive example.

Also, other film than the Al—Oₓ film in the tunnel barrier layer 6 was deposited by a DC magnetron sputtering method.

Next, the resulting product was annealed in the field annealing furnace under application of magnetic field of 10 kOe at 270° C. for 4 hours, a PtMn layer that is an antiferromagnetic layer is treated by ordered-annealing and thereby a ferromagnetic tunnel junction 9 was formed.

Subsequently, the TMR device 22 having the plane pattern shown in FIG. 6 was formed by patterning the TMR device 22 an the insulating film 26 formed under this tunnel magnetoresistive device.

Further, an insulating layer 25 having a film thickness of about 1000 nm was deposited by sputtering Al₂O₃ and further the bit line BL and the terminal pad 24 were formed by photolithography, whereby the TEG shown in FIGS. 6 and 7 was obtained.

<Sample 2>

A TEG was obtained in a method similar to that of the sample 1 except that the layer arrangement of the TMR device is as follows, that is, crystalline magnetization fixed layer/insulating layer/amorphous magnetization free layer.

Ta (3 nm)/PtMn (20 nm)/Co₉₀Fe₁₀ (2.5 nm)/Ru (0.8 nm)/Co₉₀Fe₁₀ (3 nm)/Al (1 nm)-Oₓ/(Co₉₀Fe₁₀)₈₀B₂₀ (3 nm)/Ta (5 nm)

It was confirmed through the observation by the TEM (transmission electron microscope) that (Co₉₀Fe₁₀)₈₀B₂₀ has an amorphous structure.

<Sample 3>

A TEG was obtained in a method similar to that of the sample 1 except that the layer arrangement of the TMR device is as follows, that is, amorphous magnetization fixed layer/insulating layer/amorphous magnetization free layer.

Ta (3 nm)/PtMn (20 nm)/Co₉₀Fe₁₀ (2.5 nm)/Ru (0.8 nm)/Co₉₀Fe₁₀)₈₀B₂₀ (3 nm)/Al (1 nm)-Oₓ/(CO₉₀Fe₁₀)₈₀B₂₀ (3 nm)/Ta (5 nm)

<Sample 4>

A TEG was obtained in a method similar to that of the sample 1 except that the layer arrangement of the TMR device is as follows, that is, amorphous magnetization fixed layer/insulating layer/crystalline magnetization free layer.

Ta (3 nm)/PtMn (20 nm)/Co₉₀Fe₁₀ (2.5 nm)/Ru (0.8 nm)/(Co₉₀Fe₁₀)₈₀B₂₀ (3 nm)/Al (1 nm)-Oₓ/Co₉₀Fe₁₀ (3 nm)/Ta (5 nm)

<Sample 5>

A TEG was obtained in a method similar to that of the sample 1 except that the layer arrangement of the TMR device is as follows, that is, crystalline magnetization fixed layer/insulating layer/crystalline magnetization free layer.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ/CO₇₅Fe₂₅ (3 nm)/Ta (5 nm)

<Sample 6>

A TEG was obtained in a method similar to that of the sample 1 except that the layer arrangement of the TMR device is as follows, that is, crystalline magnetization fixed layer/insulating layer/amorphous magnetization free layer.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ/(Co₉₀Fe₁₀)₈₀B₂₀ (3 nm)/Ta (5 nm)

<Sample 7>

A TEG was obtained in a method similar to that of the sample 1 except that the layer arrangement of the TMR device is as follows, that is, amorphous magnetization fixed layer/insulating layer/crystalline magnetization free layer.

Ta (3 nm)/PtMn (20 nm)/CO₇₅Fe₂₅ (2.5 nm)/Ru (0.8 nm)/Co₉₀Fe₁₀)₈₀B₂₀ (3 nm)/Al (1 nm)-Oₓ/CO₇₅Fe₂₅ (3 nm)/Ta (5 nm)

<Sample 8>

A TEG was obtained in a method similar to that of the sample 1 except that the layer arrangement of the TMR device is as follows, that is, amorphous magnetization fixed layer/insulating layer/amorphous magnetization free layer and that the two ferromagnetic layers (first and second magnetization fixed layers) of the laminated ferri structure are both made of amorphous ferromagnetic materials.

Ta (3 nm)/PtMn (20 nm)/(Co₉₀Fe₁₀)₈₀B₂₀ (2.5 nm)/Ru (0.8 nm)/(Co₉₀Fe₁₀)₈₀B₂₀ (3 nm)/Al (1 nm)-Oₓ/(Co₉₀Fe₁₀)₈₀B₂₀ (3 nm)/Ta (5 nm)

<Sample 9)

A TEG was obtained in a method similar to that of the sample 1 except that the layer arrangement of the TMR device is as follows, that is, crystalline magnetization fixed layer/insulating layer/amorphous magnetization free layer and that the (Co₉₀Fe₁₀)₉₀Si₁₀ was used as the amorphous ferromagnetic material.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ/(Co₉₀Fe₁₀)₉₀Si₁₀ (3 nm)/Ta (5 nm)

<Sample 10>

A TEG was obtained in a method similar to that of the sample 1 except that the layer arrangement of the TMR device is as follows, that is, crystalline magnetization fixed layer/insulating layer/amorphous magnetization free layer and that the (Co₉₀Fe₁₀)₉₀C₁₀ was used as the amorphous ferromagnetic material.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ(Co₉₀Fe₁₀)₉₀C₁₀ (3 nm)/Ta (5 nm)

<Sample 11>

A TEG was obtained in a method similar to that of the sample 1 except that the layer arrangement of the TMR device is as follows, that is, crystalline magnetization fixed layer/insulating layer/amorphous magnetization free layer and that the (Co₉₀Fe₁₀)₉₀P₁₀ was used as the amorphous ferromagnetic material.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ(Co₉₀Fe₁₀)₉₀P₁₀ (3 nm)/Ta (5 nm)

<Sample 12>

A TEG was obtained in a method similar to that of the sample 1 except that the layer arrangement of the TMR device is as follows, that is, crystalline magnetization fixed layer/insulating layer/amorphous magnetization free layer and that the (Co₉₀Fe₁₀)₈₀Si₁₀B₁₀ was used as the amorphous ferromagnetic material.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ (Co₉₀Fe₁₀)₈₀Si₁₀B₁₀ (3 nm)/Ta (5 nm)

<Sample 13>

A TEG was obtained in a method similar to that of the sample 1 except that the layer arrangement of the TMR device is as follows, that is, crystalline magnetization fixed layer/insulating layer/amorphous magnetization free layer and that the (Co₉₀Fe₁₀)₈₀Zr₁₀B₁₀ was used as the amorphous ferromagnetic material.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ (Co₉₀Fe₁₀)₈₀Zr₁₀B₁₀ (3 nm)/Ta (5 nm)

<Sample 14>

A TEG was obtained in a method similar to that of the sample 1 except that the layer arrangement of the TMR device is as follows, that is, crystalline magnetization fixed layer/insulating layer/amorphous magnetization free layer and that the (Co₉₀Fe₁₀)₈₀Ta₁₀B₁₀ was used as the amorphous ferromagnetic material.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ(Co₉₀Fe₁₀)₈₀Ta₁₀B₁₀ (3 nm)/Ta (5 nm)

<Sample 15>

A TEG was obtained in a method similar to that of the sample 1 except that the layer arrangement of the TMR device is as follows, that is, crystalline magnetization fixed layer/insulating layer/amorphous magnetization free layer and that the (Co₉₀Fe₁₀)₉₀B₁₀ was used as the amorphous ferromagnetic material.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ(Co₉₀Fe₁₀)₉₀B₁₀ (3 nm)/Ta (5 nm)

<Sample 16>

A TEG was obtained in a method similar to that of the sample 1 except that the layer arrangement of the TMR device is as follows, that is, crystalline magnetization fixed layer/insulating layer/amorphous magnetization free layer and that the (Co₉₀Fe₁₀)₇₀B₃₀ was used as the amorphous ferromagnetic material.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ(CO₉₀Fe₁₀)₇₀B₃₀ (3 nm)/Ta (5 nm)

<Sample 17>

A TEG was obtained in a method similar to that of the sample 1 except that the layer arrangement of the TMR device is as follows, that is, crystalline magnetization fixed layer/insulating layer/amorphous magnetization free layer and that the (Co₉₀Fe₁₀)₆₅B₃₅ was used as the amorphous ferromagnetic material.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ(CO₉₀Fe₁₀)₆₅B₃₅ (3 nm)/Ta (5 nm)

A TEG was obtained in a method similar to that of the sample 1 except that the layer arrangement of the TMR device is as follows, that is, crystalline magnetization fixed layer/insulating layer/amorphous magnetization free layer and that the (Co₉₀Fe₁₀)₆₀B₄₀ was used as the amorphous ferromagnetic material.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ(Co₉₀Fe₁₀)₆₀B₄₀ (3 nm)/Ta (5 nm)

<Sample 19>

A TEG was obtained in a method similar to that of the sample 1 except that the layer arrangement of the TMR device is as follows, that is, crystalline magnetization fixed layer/insulating layer/amorphous magnetization free layer and that the (Co₉₀Fe₁₀)₉₅B₅ was used as the amorphous ferromagnetic material.

Ta (3 nm)/PtMn (20 nm)/CO₇₅Fe₂₅ (2.5 nm)/Ru (0.8 nm)/CO₇₅Fe₂₅ (3 nm)/Al (1 nm)-Oₓ(CO₉₀Fe₁₀)₉₅B₅ (3 nm)/Ta (5 nm)

Then, with respect to the TEGs of the thus obtained samples 1 to 19, TMR ratios, dispersions of coercivity and rectangle ratios were measured as follows.

(Measurement of TMR Ratio)

While the ordinary magnetic memory apparatus such as the MRAM inverts the magnetization of the magnetoresistive device with application of an electric current magnetic field to write information, in the inventive examples, resistance values were measured by magnetizing the magnetoresistive device with application of the external magnetic field. That is, first, the external magnetic field for inverting the magnetization direction of the magnetization free layer of the TMR device 22 was applied to the magnetization free layer in parallel to the easy axis of the magnetization. The magnitude of the external magnetic field for measuring the resistance value was selected to be 500 Oe.

Next, at the same time the magnetic field was applied to the magnetization free layer from one side of the easy axis of the magnetization in a range of from −500 Oe to +500 Oe, a tunnel electric current is caused to flow to the ferromagnetic tunnel junction by adjusting a bias voltage applied to the terminal pad 23 of the word line WL and the terminal pad 24 of the bit line BL such that it may reach 100 mV. Resistance values relative to the respective external magnetic fields obtained at that time were measured. Then, TMR ratios were calculated from resistance values obtained in the condition in which the magnetization directions of the magnetization fixed layer and the magnetization free layer are in the anti-parallel state and in which the resistance is high and resistance values obtained in the condition in which the magnetization directions of the magnetization fixed layer and the magnetization free layer are in the parallel state and in which the resistance is low.

From a standpoint of obtaining satisfactory read characteristics, the TMR ratio should preferably be selected to be higher than 45%.

(Dispersions of Coercivity Hc)

R-H curves were obtained by the above-described TMR ratio measuring methods. Then, mean values of the resistance values obtained in the state in which the magnetization directions of the magnetization fixed layer and the magnetization free layer are in the anti-parallel state and in which the resistance is high and the resistance values obtained in the state in which the magnetization directions of the magnetization fixed layer and the magnetization free layer are in the parallel state and in which the resistance is low are calculated from the R-H curves, and the value of the external magnetic field under which the resistance value of this average value can be obtained was set to the coercivity Hc. A standard deviation Δ Hc was obtained by measuring this coercivity Hc of the same device (TEG) 50 times. Then, Δ Hc/(mean value of Hc) was set to dispersion of the value of the coercivity Hc.

From a standpoint of improving write characteristics, the coercivity Hc should preferably be selected to be less than 6%, more preferably selected to be less than 4%.

(Measurement of Rectangle Ratio)

Rectangle ratios of waveforms were calculated from the R-H curves. That is, a ratio (R2max−R2min)/(R1max−Rmin) between R1max−R1min in the R-H curve obtained in the magnetic field range from −500 Oe to +500 Oe upon measurement and R2max−R2 min was calculated and this value was set to the rectangle ratio.

From a standpoint of improving the write characteristic, the rectangle ratio should preferably be selected to be greater than 0.9 (90%).

The table 1 shows the TMR ratios and the dispersions of the coercivity Hc with respect to respective samples 1 to 19.

The results on the table 1 will be considered below. Any of the samples has the layer arrangement of the antiferromagnetic layer/first magnetization fixed layer (pinned layer)/nonmagnetic layer/second magnetization fixed layer (reference layer)/insulating layer (tunnel barrier layer)/magnetization free layer.

First, the samples 1 to 4 are compared with each other.

Having compared the sample 2 in which the ferromagnetic layer (adjoining the lower surface of the insulating layer) disposed under the insulating layer (tunnel barrier layer) corresponding to the intermediate layer of the present invention is made of the crystalline ferromagnetic material and in which the ferromagnetic layer (adjoining the upper surface of the insulating layer) disposed above the insulating layer is made of the amorphous ferromagnetic material with the samples 1, 3 and 4, it is to be understood that its TMR ratio is high, its dispersion of the coercivity Hc is small and that its rectangle ratio is satisfactory.

Accordingly, when the amorphous ferromagnetic material is used to form as the magnetization free layer, the amorphous ferromagnetic material should preferably be used on the intermediate layer and the crystalline ferromagnetic material should preferably be used to form the ferromagnetic layer.

Having compared the samples 5 to 8, it is to be understood that each of these samples has an arrangement in which the composition of the crystalline ferromagnetic material CoFe of the samples 1 to 4 is changed to CO₇₅Fe₂₅. The sample 6 in which the magnetic layer adjoining the lower surface of the insulating layer is made of the crystalline ferromagnetic material and in which the magnetic layer adjoining the upper surface of the insulating layer is made of the amorphous ferromagnetic material similarly as described above has better results than those of other samples.

While the crystalline ferromagnetic material for use with the magnetization fixed layer containing the case of the laminated ferri structure is not limited in particular, from a standpoint of obtaining a higher TMR ratio, a material containing Co, Fe (Ni may be contained) as main components and of which spin polarizability is large such as CO₇₅Fe₂₅ should preferably be used.

Next, the samples 9 to 14 have the layer arrangement of the sample 6 modified such that the ferromagnetic material of the magnetization free layer was changed from CoFeB to other amorphous ferromagnetic materials.

To be concrete, elements such as B, Si, C, P, Zr, Ta are added to the CoFe magnetic alloy to produce amorphous ferromagnetic materials.

Since these samples have the structure similar to that of the sample 6 in which the magnetization free layer made of the amorphous ferromagnetic material is disposed above the intermediate layer and in which the magnetization fixed layer made of the crystalline ferromagnetic material is disposed under the intermediate layer, TMR ratios thereof are higher than 45%, dispersions of coercivity Hc thereof are less than 4%, rectangle ratios thereof are higher than 95% and hence TMR devices have excellent magnetic properties. Thus, when the TMR device is applied to the magnetic memory apparatus such as the MRAM, the magnetic memory apparatus can exhibit excellent write and read characteristics.

Accordingly, it is possible to use materials in which more than one kind or two kinds of elements selected from B, Si, C, P, Zr, Ta are added to the CoFe alloy as the amorphous ferromagnetic materials.

Other elements may be added to the alloy so long as resultant alloys become amorphous ferromagnetic materials and generate high spin polarizabilities and large variations in magnetoresistance. Rare earth elements such as Al, Ti, Nb, Hf, Y, La, Ce, Pr, Nd, Pm, Sm, Eu, Gd, Tb, Dy, Ho, Er, Tm, Yb, Lu also can be used as additive elements.

Next, the samples 15 to 19 have the layer arrangement of the sample 6 modified such that the CoFeB composition of the magnetization free layer was changed.

In the sample 18, although the content of additive element B is 40 atomic %, its TMR ratio is smaller than those of other samples. When the TMR device is applied to the MRAM, since it is desired that its TMR ratio should be higher than 45%, it is desired that the content of the additive element B should be less than 35 atomic %.

Also, in the sample 19, while the content of the additive element B is 5 atomic %, its TMR ratio is slightly as low as 44% and the dispersion of the coercive force Hc is slightly as large additive element B have excellent results and hence it is desired that the content of the additive element B should be greater than 10 atomic %.

This may also be true in the case in which the additive element is other element than B. If the content of the additive element is too small, then effects achieved by the amorphous substance are weakened and hence properties of crystalline ferromagnetic materials are emphasized. On the other hand, if the content of the additive element is too large, then the composition of the amorphous ferromagnetic material is displaced from the composition range to form the amorphous substance so that bad influences such as small TMR ratios will appear due to the reasons that stable magnetic properties cannot be obtained, the amount of the component of Fe-group magnetic element being small.

Then, it is desired that the added amount of the additive element should be selected in a range of from 10 to 35 atomic %.

The magnetoresistive device (TMR device, etc.) of the present invention is not limited to the aforementioned magnetic memory apparatus but it can be applied to a magnetic head, a hard disk or a magnetic sensor with this magnetic head mounted thereon, an integrated circuit chip and further various kinds of electronic equipment and electronic devices such as personal computers, personal digital assistants and mobile phones.

The present invention is not limited to the above-mentioned inventive examples but can take various arrangements without departing from the gist of the present invention.

According to the magnetoresistive device of the present invention, the rectangle ratio of the R-H curve can be improved, the coercivity can be decreased and the dispersion of the coercivity can be improved.

Also, since the magnetoresistive ratio (variation in magnetoresistance) can be increased and the bias voltage dependence of the magnetoresistive ratio can be improved, it becomes possible to realize high magnetoresistive ratio (variation in magnetoresistance).

Consequently, when the magnetoresistive device is applied to the magnetic memory apparatus, the excellent write characteristic can be obtained so that the write error can be decreased, and also the excellent read characteristic can be obtained so that the read error can be decreased.

Also, according to the magnetic memory apparatus of the present invention, it is possible to realize excellent write and read characteristics.

1. In a magnetoresistive device having a pair of ferromagnetic layers opposed to each other to obtain variations in magnetoresistance by an electric current flowing to the direction perpendicular to the film plane, a magnetoresistive device characterized in that said pair of ferromagnetic layers is composed of a magnetization fixed layer made of a crystalline ferromagnetic layer provided under said intermediate layer and a magnetization free layer being made of an amorphous ferromagnetic layer being provided above said intermediate layer.

2. A magnetoresistive device according to claim 1, characterized in that said magnetoresistive device has a laminated ferri structure.

3. A magnetoresistive device according to claim 1, characterized in that said magnetoresistive device is a tunnel magnetoresistive device using a tunnel barrier layer made of an insulating material or a semiconducting material as said intermediate layer.

4. A magnetic memory apparatus comprising:
a magnetoresistive device having a pair of ferromagnetic layers opposed to each other to obtain variations in magnetoresistance by an electric current flowing to the direction perpendicular to the film plane;
a word line a bit line sandwiching said magnetoresistive device in the thickness direction, wherein said magnetic memory apparatus includes said pair of ferromagnetic layers composed of a magnetization fixed layer made of a crystalline ferromagnetic layer provided under said intermediate layer and a magnetization free layer being made of an amorphous ferromagnetic layer being provided above said intermediate layer.

5. A magnetic memory apparatus according to claim 4, characterized in that said magnetoresistive device has a laminated ferri structure.

6. A magnetic memory apparatus according to claim 4, characterized in that said magnetoresistive device is a tunnel magnetoresistive device using a tunnel barrier layer made of an insulating material or a semiconducting material as said intermediate layer.
